(19) United States
(12) Patent Application Publication
(10) Pub. No.: US 2009/0244844 A1
(43) Pub. Date: Oct. 1, 2009

(54) Heat-dissipating module

(75) Inventors: Chin-Chun Liao, Taipei City (TW); Meng-Hung Ko, Taipei County (TW)

Correspondence Address: BACON & THOMAS, PLLC, 625 SLATERS LANE, FOURTH FLOOR, ALEXANDRIA, VA, 22314-1176, US

(73) Assignee: TAI-SOL ELECTRONICS CO., LTD., Taipei City (TW)

(21) Appl. No.: 12/213,247

(22) Filed: Jun. 17, 2008

(30) Foreign Application Priority Data
Apr. 1, 2008 (TW) 97205587

(51) Int. Cl. H05K 7/20

(52) U.S. Cl. 361/697

(57) ABSTRACT

A heat-dissipating module includes a heat sink, a plurality of fixtures, and a plurality of fasteners. The heat sink includes a plurality of fins and a plurality of hollowed portions located at a periphery thereof. Each of the fixtures includes a support portion and two lap joint portions. Each of the two lap joint portions has a fasten hole. Each of the support portions has a support hole. Each of the fixtures corresponds to one of the hollowed portions. The two lap joint portions of each fixture are mounted to a top edge of the fins and close to two sides of the support portion. The fasteners fasten the lap joint portions to the heat sink. In this way, the heat sink and the fixtures are fastened with each other to enhance the structural durability of the heat-dissipating module. In addition, the heat-dissipating module is small-sized, taking less space.

### BACKGROUND OF THE INVENTION

1. Field of the Invention

The present invention relates generally to heat-dissipating devices, and more particularly, to a heat-dissipating module.

2. Description of the Related Art

A general heat-dissipating module applied to a central processing unit (CPU) of a computer is composed of a heat sink and a cooling fan. The heat sink is in contact with the CPU for absorbing the heat generated by the CPU and transferring the heat to fins of the heat sink, and then the cooling fan blows the fins to dissipate the heat of the fins.

As shown in FIGS. 1 and 2, a conventional heat-dissipating module 1 is composed of a heat sink 2, a protective cap 3, a cooling fan 4, and four springs 9. The protective cap 3 having four link holes 6 at four corners thereof is covered on the heat sink 2 and fixed to a substrate (not shown) in such a way that four linking members are inserted through the link holes 6 and the springs 9. In this way, the heat sink 2 is in contact with a CPU (not shown) located on the substrate. The cooling fan 4 having four through holes 8 located at a periphery thereof is fixed to the protective cap 3 in such a way that four screw bolts 7 are inserted through the through holes 8 respectively. In this way, the heat sink 2, the protective cap 3, and the cooling fan 4 are combined together. Because the protective cap 3 is generally made of plastic, under the double actions of high temperature and biasing forces of the springs 9, after a long time, the protective cap 3 at the link holes 6 is subject to rupture, thus disabling the heat sink 2 from close contact with the CPU.

### SUMMARY OF THE INVENTION

The primary objective of the present invention is to provide a heat-dissipating module, which is of preferable strength and durability in structure.

The secondary objective of the present invention is to provide a heat-dissipating module, which required less space.

The foregoing objectives of the present invention are attained by the heat-dissipating module composed of a heat sink, a plurality of fixtures, and a plurality of fasteners. The heat sink includes a plurality of fins and a plurality of hollowed portions located at a periphery thereof. Each of the fixtures includes a support portion, and two lap joint portions extending parallel outward from two sides of each of the support portions. Each of the two lap joint portions has a fasten hole. Each of the support portions has a support hole. Each of the fixtures corresponds to one of the hollowed portions. Each of the support portions is located in the corresponding hollowed portion. The two lap joint portions of each fixture are mounted to a top edge of the fins and close to two sides of the support portion. Each of the fasteners is inserted through at least one of the support holes of each fixture to be fixed to the heat sink, fastening the lap joint portions of each fixture to the heat sink. In this way, the cooling fan and the heat sink are fastened with each other to enhance the structural durability of the present invention. In addition, the present invention is small-sized, taking less space.

### BRIEF DESCRIPTION OF THE DRAWINGS

FIG. 1 is an exploded view of the conventional heat-dissipating module.

FIG. 2 is a perspective view of the conventional heat-dissipating module.

FIG. 3 is a perspective view of a first preferred embodiment of the present invention.

FIG. 4 is a partially exploded view of the first preferred embodiment of the present invention.

FIG. 5 is a perspective view of a second preferred embodiment of the present invention.

FIG. 6 is a partially exploded view of the second preferred embodiment of the present invention.

FIG. 7 is a partially exploded view of a third preferred embodiment of the present invention.

FIG. 8 is a perspective view of the third preferred embodiment of the present invention.

FIG. 9 is a partially exploded view of a fourth preferred embodiment of the present invention.

FIG. 10 is a perspective view of a fifth preferred embodiment of the present invention.

FIG. 11 is an upside-down perspective view of the fifth preferred embodiment of the present invention.

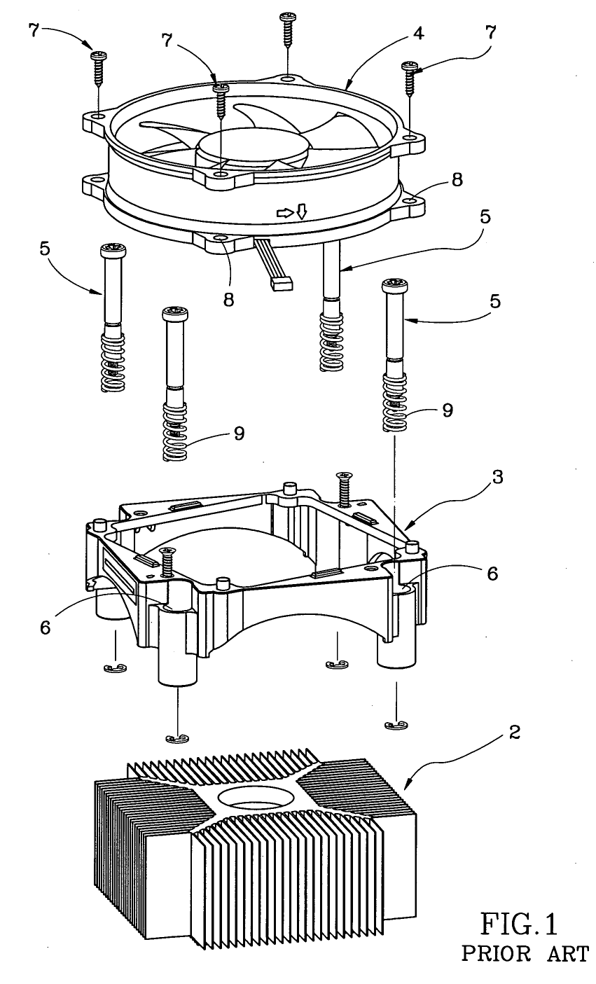

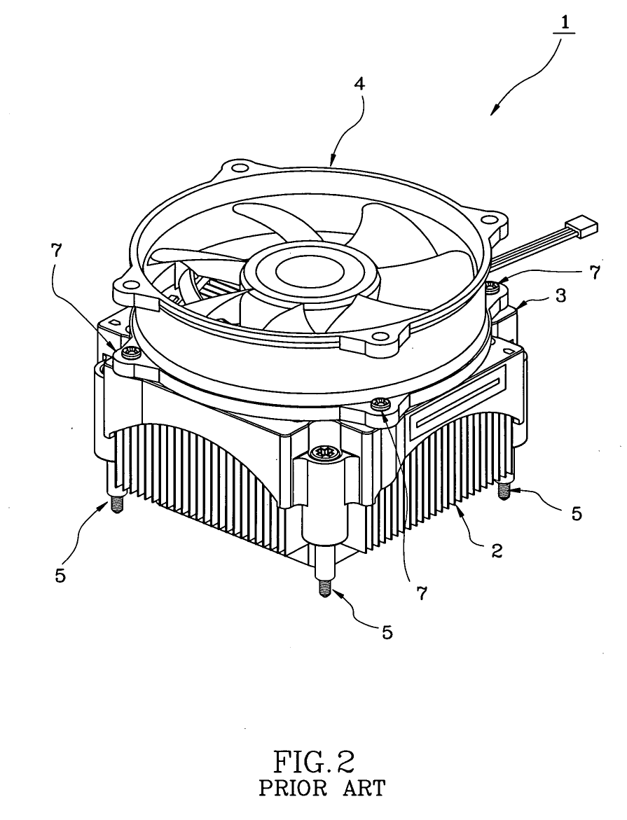

### DETAILED DESCRIPTION OF PREFERRED EMBODIMENTS

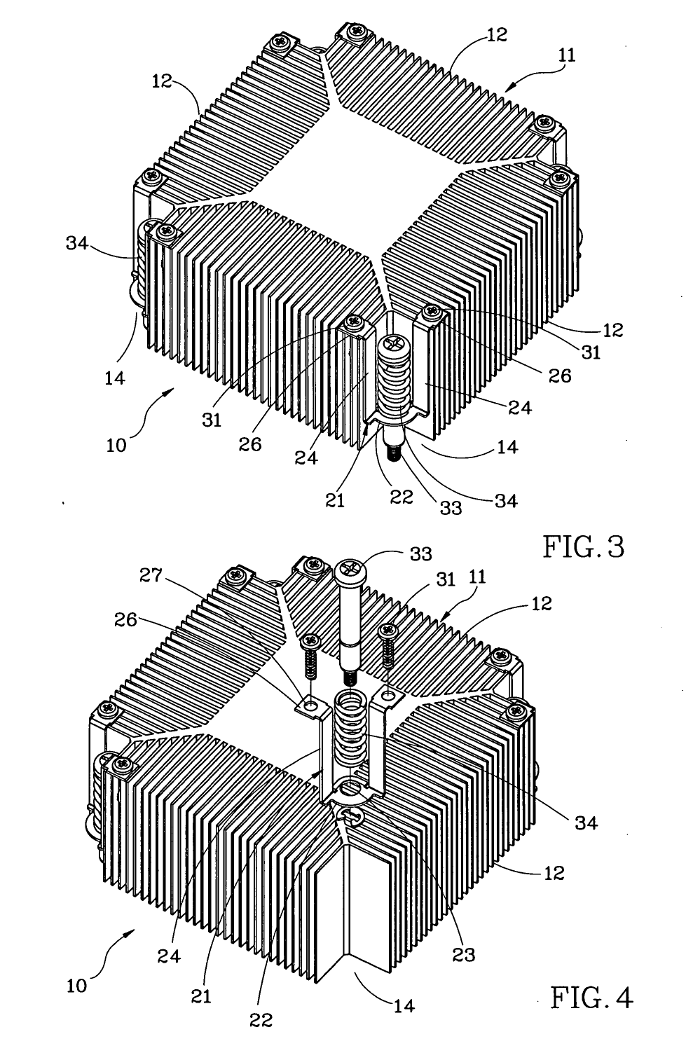

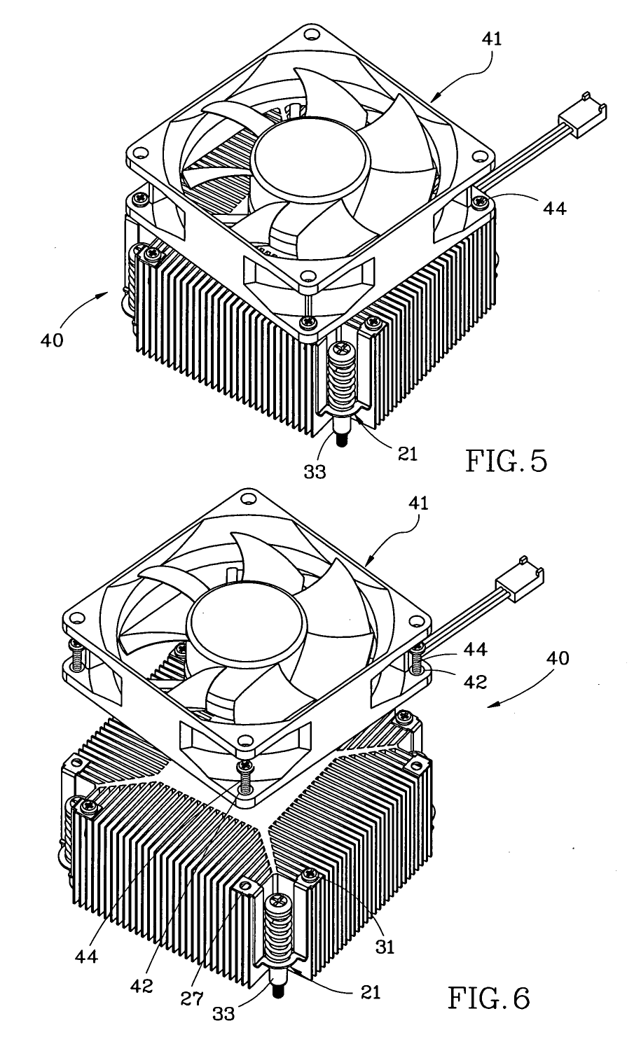

Referring to FIGS. 3 and 4, a heat-dissipating module 10 of a first preferred embodiment of the present invention is composed of a heat sink 11, a plurality of fixtures 21, a plurality of fasteners 31, and a plurality of linking members.

The heat sink 11 includes a plurality of fins 12 and a plurality of hollowed portions 14 located at a periphery thereof.

The fixtures 21 are made of metal or heat-resistant material and each include a support portion 22, two extension parts 24 extending upward from two sides of the support portion 22 for a predetermined length, and two lap joint portions 26 extending parallel outward from respective top edges of the two extension parts 24. Each of the lap joint portions 26 has a fasten hole 27. Each of the support portions 22 has a support hole 23. Each of the fixtures 21 corresponds to one of the hollowed portions 14, each of the support portions 22 being located in the corresponding hollowed portion 14. The lap joint portions 26 of each fixture 21 are mounted to a top edge of the fins 12 and close to two sides of the corresponding hollowed portion 14. Each of the extension parts 24 is stopped against one of the fins 12.

The fasteners 31, which are screw bolts in this embodiment, each are inserted through one of the fasten holes 27 and fixed to between two of the fins 12 of the heat sink 11 to fasten the lap joint portion 26 to the heat sink 11. In addition, each of the fasteners 31 is not limited to the screw bolt and can be an alternative, like latch.

The linking members 33, which are screw bolts in this embodiment, each include a spring 34. Each of the linking members 33 is inserted through one of the support holes 23 and is stopped against one of the support portions 22 by one of the springs 34, for connection with a circuit board (now shown) or another heat-dissipating device (not shown). In addition, each of the linking members 33 is not limited to the screw bolt and can be an alternative, like latch.

In light of the above, the fixtures 21 are fixed to the fins 12 of the heat sink 11 and connected with a circuit board (not shown) by the lining members 33, and then the heat sink 11 at a bottom side thereof can be connected with a heat-generating member (not shown), like CPU, for thermal dissipation.

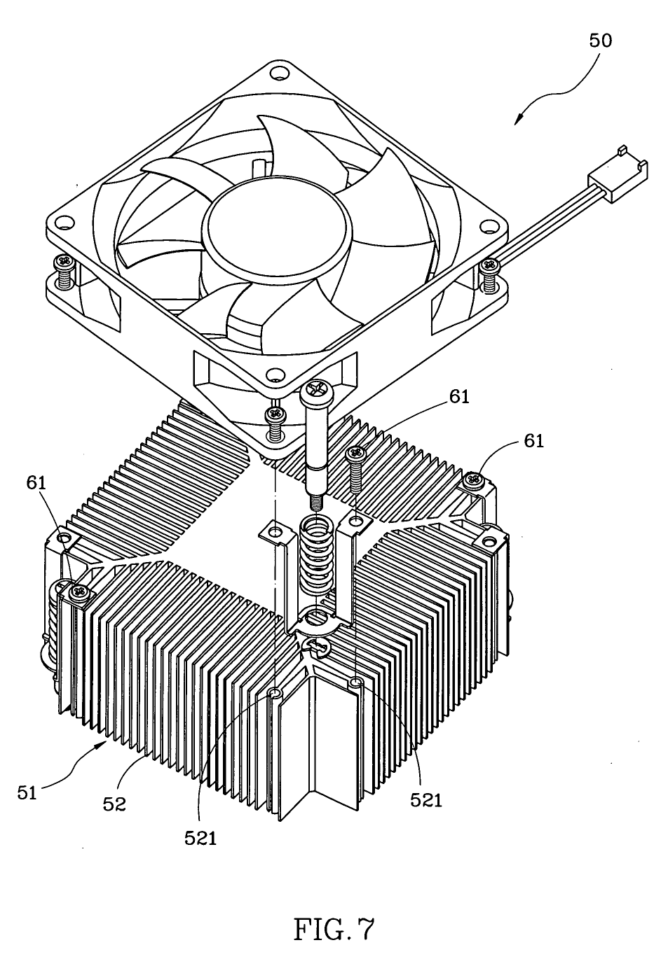

Referring to FIGS. 5 and 6, a heat-dissipating module 40 in accordance with a second preferred embodiment of the present invention is similar to the first embodiment and different as recited below.

The heat-dissipating module 40 further includes a cooling fan 41. The cooling fan 41 has four through holes 42 formed at four corners thereof. Each of the through holes 42 selectively corresponds to one of the fasten holes 27, through which the fastener 31 is not inserted. The cooling fan 41 is fixed to the heat sink 11 in such a way that a plurality of screw bolts 44 are inserted through the through holes 42 respectively to be screwed with the fasten holes 27. When the cooling fan 41 is fixed to the heat sink 11, the airstream generated by the cooling fan 41 can take the heat out of the heat sink 11 for more efficient thermal dissipation.

When the heat sink 11 is mounted to a circuit board (not shown), the overall pressure is taken by the linking members and the fixtures 21, such that the linking pressure does not work on the cooling fan 41 and thus the linking structure of the cooling fan 41 is not subject to crack or rupture as the prior art is. In addition, the fixtures 21 are located in the hollowed portions 14, not extending out of the heat sink, such that the overall size of the combination of the present invention is small to take less space.

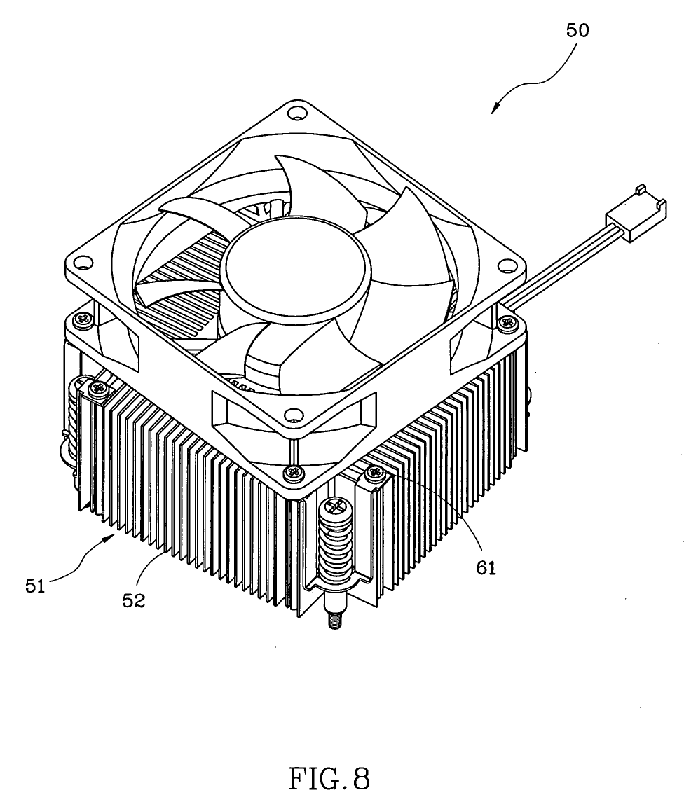

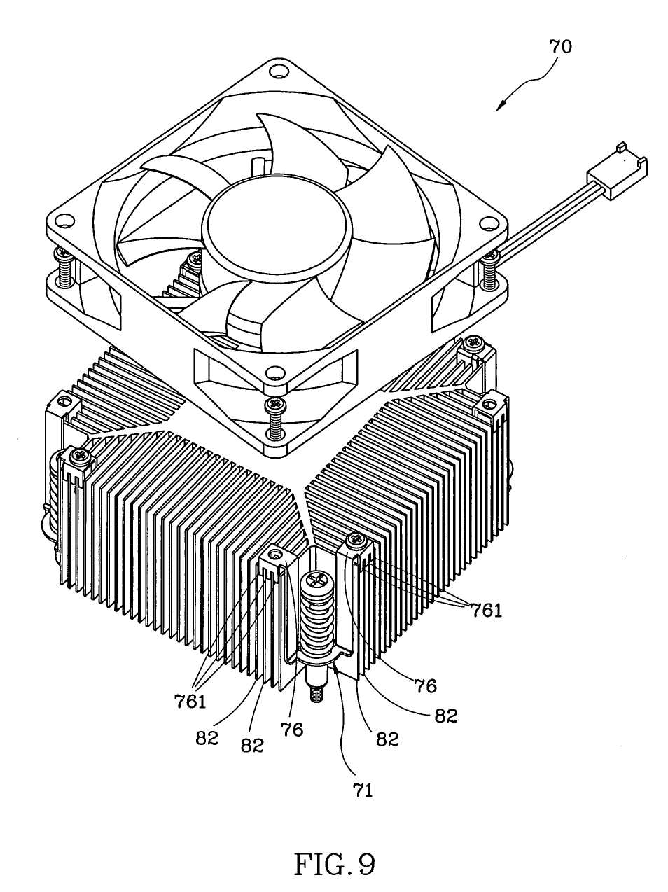

Referring to FIGS. 7 and 8, a heat-dissipating module 50 in accordance with a third preferred embodiment of the present invention is similar to the first embodiment and different as recited below.

A plurality of threaded holes 521 are formed at predetermined ones of the fins 52 of the heat sink 51. Each of the fasteners 61 is fixed into one of the threaded holes 521. Except the way of connection between the fasteners 61 and the fins 52, the other structures and the attained effects of the third embodiment are identical to those of the first embodiment, such that no more recitation is necessary.

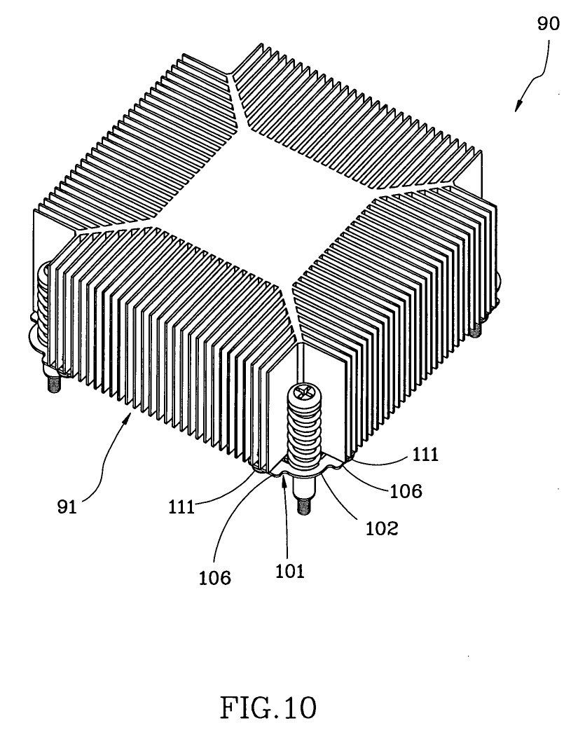

Referring to FIG. 9, a heat-dissipating module 70 in accordance with a fourth preferred embodiment of the present invention is similar to the first embodiment and different as recited below.

Each of the lap joint portions 76 of the fixtures 71 includes a plurality of claws 761 extending downward. Each of the claws 761 is engaged between two of the fins 82. Except the way of connection between the lap joint portions 76 and the fins 82, the other structures and the attained effect of the fourth embodiment are identical to those of the first embodiment, such that no more recitation is necessary.

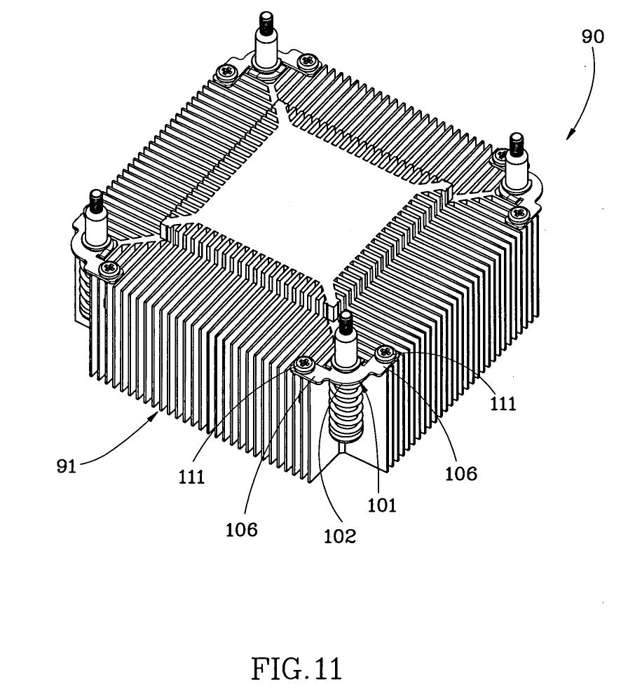

Referring to FIGS. 10 and 11, a heat-dissipating module 90 in accordance with a fifth preferred embodiment of the present invention is similar to the first embodiment and different as recited below.

Each of the support portions 102 of the fixtures 101 does not have the two extension parts mentioned in the aforementioned embodiments. The two lap joint portions 106 extend parallel outward from two sides of the supports 102 respectively and are fixed beneath the heat sink 91 by a plurality of the fasteners 111.

In conclusion, the linking pressure of the heat sink is taken by the fasteners and the fixtures, such that the linking pressure does not work on the cooling fan and the cooling fan is not subject to crack or rupture due to the pressure and high heat. In addition, the fixtures are located in the hollowed portions, not extending out of the heat sink, such that the overall combination of the heat-dissipating module of the present invention is preferably small, taking less space.

Although the present invention has been described with respect to specific preferred embodiments thereof, it is no way limited to the details of the illustrated structures but changes and modifications may be made within the scope of the appended claims.

What is claimed is:

1. A heat-dissipating module comprising:
a heat sink having a plurality of fins and a plurality of hollowed portions formed at a periphery thereof;
a plurality of fixtures, each of which has a support portion and two lap joint portions extending parallel outward from two sides of said support portion, each of said lap joint portions having a fasten hole, each of said support portions having a support hole, each of said fixtures corresponding to one of said hollowed portions, each of said support portions being located in said corresponding hollowed portion, said two lap joint portions of each said fixture being mounted to a top edge of said fins and close to two sides of said corresponding hollowed portion; and
a plurality of fasteners each inserted through at least one of said fasten holes of said fixtures to be fixed to said heat sink, whereby said lap joint portions are fixed to the heat sink.

2. The heat-dissipating module as defined in claim 1, wherein each of said lap joint portions further comprises a plurality of claws extending downward therefrom, each of said claws being engaged between two of said fins.

3. The heat-dissipating module as defined in claim 1, wherein each of said fixtures is fixed between two of said fins.

4. The heat-dissipating module as defined in claim 1, wherein said heat sink further comprises a plurality of threaded holes, each of said threaded holes being formed at predetermined ones of said fins; each of said fasteners is fixed into one of said threaded holes.

5. The heat-dissipating module as defined in claim 1, wherein each of said fixtures further comprises two extension parts located between said support portion and said two lap joint portions respectively, each of said two extension parts being stopped against one of said fins.

6. The heat-dissipating module as defined in claim 1 further comprising a plurality of linking members, wherein each of said linking members has a spring and is inserted through one of said support holes in such a way that said spring is stopped against said support portion.

7. The heat-dissipating module as defined in claim 1 further comprising a cooling fan, wherein said cooling fan has four through holes formed at four corners thereof, each of said through holes selectively corresponding to one of said fasten holes of each said fixture.

8. The heat-dissipating module as defined in claim 1, wherein each of said fixtures is made of metal.

9. The heat-dissipating module as defined in claim 1, wherein each of said support portions comprises two extension parts extending upward from two sides of said support portion for a predetermined length; said two lap joint portions of each said fixture extend parallel outward from said two extension parts respectively.
